(19) United States
(12) Patent Application Publication
(10) Pub. No.: US 2014/0221817 A1
(43) Pub. Date: Aug. 7, 2014

(54) METHOD FOR GENERATING ATTENUATION CORRECTION FOR A COMBINED MAGNETIC RESONANCE-POSITRON EMISSION TOMOGRAPHY DEVICE

(71) Applicant: Siemens Aktiengesellschaft, Munich (DE)

(72) Inventors: Bassim AKLAN, Erlangen (DE); Matthias FENCHEL, Erlangen (DE); Annemarie HAUSOTTE, Erlangen (DE); René KARTMANN, Nuremberg (DE); Ralf LADEBECK, Erlangen (DE); Daniel PAULUS, Nuremberg (DE); Harald H. QUICK, Erlangen (DE)

(73) Assignee: SIEMENS AKTIENGESELLSCHAFT, Munich (DE)

(21) Appl. No.: 14/158,944

(22) Filed: Jan. 20, 2014

(30) Foreign Application Priority Data
Feb. 1, 2013 (DE) 102013201701.4

(51) Int. Cl. G01R 33/48

(52) U.S. Cl. CPC G01R 33/481
USPC 600/411

(57) ABSTRACT

A method, a computer program product and a computer readable storage medium are disclosed for generating a global attenuation map used for attenuation correction of positron emission tomography image data sets in a combined magnetic resonance-positron emission tomography device. In an embodiment, during the course of detecting hardware components of the combined magnetic resonance-positron emission tomography device and determining positions of the detected hardware components relative to a patient support, the global attenuation map is generated as a function of the detected hardware components.

### PRIORITY STATEMENT

The present application hereby claims priority under 35 U.S.C. §119 to German patent application number DE 102013201701.4 filed Feb. 1, 2013, the entire contents of which are hereby incorporated herein by reference.

### FIELD

At least one embodiment of the present invention generally relates to a method for generating attenuation correction for a combined magnetic resonance-positron emission tomography device, a corresponding computer program product which permits the execution of such a method, an electronically readable data carrier and/or a combined magnetic resonance-positron emission tomography device therefor.

### BACKGROUND

Imaging methods for representing objects to be examined, in particular for determining material properties, the material arrangement and expansion or the like are widely available, in particular in the medical application thereof.

The image data of various known medical examination devices enable different conclusions to be drawn. Whilst X-ray based image data enable information to be obtained about the attenuation coefficients of the displayed object to be examined, by way of magnetic resonance tomography, information may be obtained about the proton density and/or the density of the respectively excited nuclei, relaxation parameters and other variables. Positron emission tomography, however, permits functional imaging without achieving the positional resolution of magnetic resonance tomography, for example. Thus there is a need for combined medical examination devices which enable the recording of image data of a plurality of examination devices in order to obtain amalgamated image data. Thus clearer information may be derived from this amalgamated image data, in particular for diagnosis, than by simply considering individual image data, i.e. image data from a single examination device.

Positron emission tomography (PET) is a widespread method for functional imaging. During an examination, a weak radioactive substance is administered to a person to be examined, the distribution thereof in the organism being made visible by means of PET. As a result, biochemical and physiological functions of the organism may be displayed. In this case, molecules which are marked with a radionuclide which emits positrons are used as radiopharmaceuticals. The high-energy photons produced during the annihilation of the positron by an electron in the body of the person to be examined, which are emitted at an angle of 180° relative to one another, are detected by a plurality of detectors arranged in an annular manner around the person to be examined. In each case, only coincidence events which have been recorded by two opposing detectors are evaluated. Deductions are made about the spatial distribution of the radiopharmaceutical inside the body from the registered coincident decay events and a series of sectional images is calculated. The image reconstruction in this case may take place by a filtered back projection or an iteration method, wherein the spatial resolution generally falls short of the resolution of conventional computer tomography (CT)—or magnetic resonance tomography (MRT)—systems.

When passing through matter, the photons produced during the annihilation are absorbed, wherein the likelihood of absorption is dependent on the length of the path through the matter and the corresponding absorption coefficients of the matter. Accordingly, in PET a correction of the signals is required relative to the attenuation by components which are located in the beam path. In particular, such a correction has to be undertaken when a quantitative analysis of the data is to be carried out, for example for quantifying accumulations of the marked substance (i.e. the radiopharmaceutical) in areas of the person to be examined. If the absorption of the radiation is not taken into consideration, this leads to the occurrence of artifacts, even in image reconstruction, as without absorption correction the measured activity distribution does not coincide with the actual distribution. The correction of the attenuation of the radiation requires knowledge of the position of the attenuated structures which are taken into consideration during the reconstruction of PET image data via an attenuation correction map (p-map).

An attenuation correction map may be determined by a combined PET/CT system. The correction maps may in this case be calculated from the Hounsfield values of the CT data. This procedure is enabled by the X-ray radiation of the CT being subjected, when passing through the person to be examined, to a similar attenuation as the high-energy photons when the PET signals are recorded. Moreover, by way of such systems, the high positional resolution of CT is able to be combined with the functional imaging of PET.

CT devices have the drawback, however, that damaging X-ray radiation is used and that, without contrast devices/agents/dyes, only low soft tissue contrast is able to be achieved. In particular during functional imaging of the brain, however, high soft tissue contrast is desirable.

A high positional resolution with at the same time high soft tissue contrast as well as functional imaging may be achieved by a combination of PET and magnetic resonance tomography (MRT). By such an installation, both high resolution images of, for example, the brain structure may be provided and functional activities in the brain may be displayed simultaneously. By way of MRT, different types of tissue may be differentiated, whilst PET makes physiological and biochemical activities visible. However, it is difficult to derive attenuation coefficients for the high-energy photons of PET imaging from MRT image data, i.e. to determine the attenuation correction map. Moreover, the recording of MRT image data requires a considerably longer acquisition period than generating computer tomographies.

In order to consider the attenuation of the emitted photons through the body, moreover, any deviations of the MRT imaging from the true geometry have an adverse effect. In this case, in particular, the regions which are located in the PET radiation path but which are not imaged by the MRT or not imaged at the correct point represent a problem. This also applies to the tissue of the patient and to hardware components used during the examination, such as patient supports, positioning aids, cushions, body coils and the like. Therefore, it is desirable to ensure correct attenuation correction.

### SUMMARY

At least one embodiment of the invention is directed to providing attenuation correction for a combined magnetic resonance-positron emission tomography device.

At least one embodiment of the invention is directed to a method. At least one embodiment of the invention is directed to a combined magnetic resonance-positron emission tomography device, a computer program product, and/or a computer readable storage medium. Advantageous embodiments of the invention are specified in the sub-claims respectively referring back thereto.

At least one embodiment according to the invention is described hereinafter with reference to the method. Features, advantages or alternative embodiments mentioned here may also be transferred to the other subjects claimed and vice versa. In other words, the subject claims which relate, for example, to a device, may also be developed by the features which are described or claimed in combination with a method. The corresponding functional features of the method are in this case implemented by corresponding modules relating to the subject-matter, in particular by hardware modules.

At least one embodiment of the invention makes use of the specific positions of the hardware components used when recording with a combined magnetic resonance-positron emission tomography device, in order to produce an attenuation map of the components.

In at least one embodiment, a method is provided which generates a global attenuation map used for attenuation correction of positron emission tomography image data sets in a combined magnetic resonance-positron emission tomography device and comprises:

detecting hardware components of the combined magnetic resonance-positron emission tomography device, which are used when generating the desired image data sets, by means of a detection unit,

determining the positions of the detected hardware components relative to a patient support of the combined magnetic resonance-positron emission tomography device by means of the detection unit and

generating the global attenuation map as a function of the detected hardware components by means of a generator unit.

Within the scope of an embodiment of the present invention, a combined magnetic resonance-positron emission tomography device is also provided for generating a global attenuation map used for attenuation correction of positron emission tomography image data sets. In this case, the combined magnetic resonance-positron emission tomography device comprises a detection unit, a processing unit with a generator unit and a control device and is designed for carrying out at least the following:

detecting hardware components of the combined magnetic resonance-positron emission tomography device, which are used when generating the desired image data sets, via the detection unit,

determining the positions of the detected hardware components relative to a patient support of the combined magnetic resonance-positron emission tomography device via the detection unit and

generating the global attenuation map as a function of the detected hardware components via the generator unit.

Moreover, at least one embodiment of the present invention describes a computer program product, in particular a computer program or software which is able to be loaded into a memory of a programmable control unit and/or a computer of a combined magnetic resonance-positron emission tomography device. By means of said computer program product, all or different embodiments of the method according to the invention previously described may be implemented when the computer program product runs in the control unit or control device of the combined magnetic resonance-positron emission tomography device. In this case, the computer program product potentially requires program segments, for example libraries and auxiliary functions, in order to implement the corresponding embodiments of the method. In other words, in particular a computer program or software, by which one of the above described embodiments of the method according to the invention may be implemented and/or which implements the embodiment, is intended to be protected by a claim relating to the computer program product. In this case, the software may be a source code which still has to be compiled and bound or which only has to be interpreted or an executable software code which only has to be loaded into the corresponding computer in order to be executed.

Moreover, at least one embodiment of the present invention further relates to a computer readable storage medium, for example a DVD, a magnetic strip or a USB stick, on which electronically readable control information, in particular software is stored. If the control information is read by the data carrier and stored in a control unit and/or computer of a combined magnetic resonance-positron emission tomography device, any of the embodiments according to the invention of the previously described method may be carried out.

The advantages of the combined magnetic resonance-positron emission tomography device according to an embodiment of the invention, of the computer program product according to an embodiment of the invention and the computer readable storage medium according to an embodiment of the invention substantially correspond to the advantages of at least one embodiment of the method according to the invention which are set forth in detail above, which is why repetition is avoided here.

### BRIEF DESCRIPTION OF THE DRAWINGS

The invention is described and explained in more detail hereinafter with reference to the example embodiments shown in the figures, in which:

FIG. 1 shows a schematic view of a combined magnetic resonance-positron emission tomography device according to an embodiment of the invention,

FIG. 2 shows a cross section of a combined magnetic resonance-positron emission tomography device according to an embodiment of the invention,

FIG. 3 shows a diagram for determining the attenuation correction factor for a plurality of functional components shown below in a patient table,

FIG. 4 shows an option for arranging different hardware components,

FIG. 5 shows a second option for arranging different components,

FIG. 6 shows a third option for arranging different components,

FIG. 7 shows a flow diagram of a method according to an embodiment of the invention and

FIG. 8 shows a schematic view of generating a global attenuation map using local attenuation maps of different hardware components.

### DETAILED DESCRIPTION OF THE EXAMPLE EMBODIMENTS

The present invention will be further described in detail in conjunction with the accompanying drawings and embodiments. It should be understood that the particular embodiments described herein are only used to illustrate the present invention but not to limit the present invention.

Accordingly, while example embodiments of the invention are capable of various modifications and alternative forms, embodiments thereof are shown by way of example in the drawings and will herein be described in detail. It should be understood, however, that there is no intent to limit example embodiments of the present invention to the particular forms disclosed. On the contrary, example embodiments are to cover all modifications, equivalents, and alternatives falling within the scope of the invention. Like numbers refer to like elements throughout the description of the figures.

Specific structural and functional details disclosed herein are merely representative for purposes of describing example embodiments of the present invention. This invention may, however, be embodied in many alternate forms and should not be construed as limited to only the embodiments set forth herein.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, term such as “below” can encompass both an orientation of above and below. The device may be otherwise oriented (rotated 90 degrees or at other orientations) and the spatially relative descriptors used herein are interpreted accordingly.

Although the terms first, second, etc. may be used herein to describe various elements, components, regions, layers and/or sections, it should be understood that these elements, components, regions, layers and/or sections should not be limited by these terms. These terms are used only to distinguish one element, component, region, layer, or section from another region, layer, or section. Thus, a first element, component, region, layer, or section discussed below could be termed a second element, component, region, layer, or section without departing from the teachings of the present invention.

In at least one embodiment, a method is provided which generates a global attenuation map used for attenuation correction of positron emission tomography image data sets in a combined magnetic resonance-positron emission tomography device and comprises:

detecting hardware components of the combined magnetic resonance-positron emission tomography device, which are used when generating the desired image data sets, by means of a detection unit,

determining the positions of the detected hardware components relative to a patient support of the combined magnetic resonance-positron emission tomography device by means of the detection unit and

generating the global attenuation map as a function of the detected hardware components by means of a generator unit.

The single global attenuation map produced in this manner according to at least one embodiment of the invention simplifies the process of generating such attenuation maps as they are simple and rapid to generate for all possible combinations of hardware components, such as for example EKG (electrocardiogram) measuring devices, patient supports, arm and leg supports, body coils, positioning aids, cushions and the like.

In an example embodiment, the detection unit and/or the generator unit are integrated in the combined magnetic resonance-positron emission tomography device which contributes to the compactness of the device.

In an advantageous embodiment, local attenuation maps of the detected hardware components are used for generating the global attenuation map by means of the generator unit. As a result, the time for generating the global attenuation map is reduced and thus the overall measuring time.

In a further embodiment, the local attenuation maps for the detected hardware components are determined by way of the above imaging methods.

In a further embodiment, the local attenuation maps for the detected hardware components are provided by a data bank linked to the detection unit. Such a provision of local attenuation maps further accelerates the overall process. Additionally, the attenuation maps for all possible combinations of hardware components may be reliably provided without having to keep generating the attenuation maps of the respective individual components in advance.

An embodiment according to the invention comprises the detected hardware components and the positions of the hardware components being monitored by a user before generating the global attenuation map. In this manner, it is ensured that the position of the hardware components provided in the system coincides with the actual position of the hardware components.

A further embodiment according to the invention is that the detected hardware components are provided with an RFID transponder (radio frequency identification transponder). As a result, information about the hardware components may be stored in the transponder and manual sources of error during subsequent identification may be eliminated. Moreover, as a result, the localization of the hardware components is simplified.

A further embodiment according to the invention provides that the specific positions of the hardware components are monitored by reading an identifying code of the RFID transponder. As a result, it may also be established whether the position of the hardware components provided in the system coincide with the actual position of the hardware components. This also eliminates potential manual sources of error.

In an advantageous embodiment, the specific positions of the hardware components are monitored by a video monitoring system. Also in this case, it is intended that the position of the hardware components provided in the system and the actual position of the hardware components coincide.

A further embodiment which is designed for such a coincidence is the monitoring of the specific positions of the hardware components by light pulse measurements, for example by a Kinect system, which also contributes to correct detection of the desired positions of the hardware components.

Within the scope of an embodiment of the present invention, a combined magnetic resonance-positron emission tomography device is also provided for generating a global attenuation map used for attenuation correction of positron emission tomography image data sets. In this case, the combined magnetic resonance-positron emission tomography device comprises a detection unit, a processing unit with a generator unit and a control device and is designed for carrying out at least the following:

detecting hardware components of the combined magnetic resonance-positron emission tomography device, which are used when generating the desired image data sets, via the detection unit,

determining the positions of the detected hardware components relative to a patient support of the combined magnetic resonance-positron emission tomography device via the detection unit and

generating the global attenuation map as a function of the detected hardware components via the generator unit.

Moreover, at least one embodiment of the present invention describes a computer program product, in particular a computer program or software which is able to be loaded into a memory of a programmable control unit and/or a computer of a combined magnetic resonance-positron emission tomography device. By means of said computer program product, all or different embodiments of the method according to the invention previously described may be implemented when the computer program product runs in the control unit or control device of the combined magnetic resonance-positron emission tomography device. In this case, the computer program product potentially requires program segments, for example libraries and auxiliary functions, in order to implement the corresponding embodiments of the method. In other words, in particular a computer program or software, by which one of the above described embodiments of the method according to the invention may be implemented and/or which implements the embodiment, is intended to be protected by a claim relating to the computer program product. In this case, the software may be a source code which still has to be compiled and bound or which only has to be interpreted or an executable software code which only has to be loaded into the corresponding computer in order to be executed.

Moreover, at least one embodiment of the present invention further relates to a computer readable storage medium, for example a DVD, a magnetic strip or a USB stick, on which electronically readable control information, in particular software is stored. If the control information is read by the data carrier and stored in a control unit and/or computer of a combined magnetic resonance-positron emission tomography device, any of the embodiments according to the invention of the previously described method may be carried out.

The advantages of the combined magnetic resonance-positron emission tomography device according to an embodiment of the invention, of the computer program product according to an embodiment of the invention and the computer readable storage medium according to an embodiment of the invention substantially correspond to the advantages of at least one embodiment of the method according to the invention which are set forth in detail above, which is why repetition is avoided here.

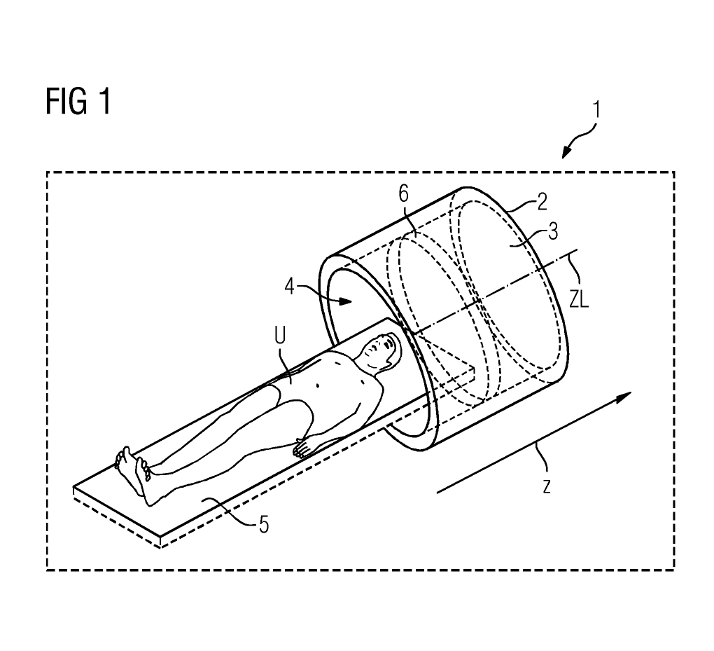

FIG. 1 shows a schematic view of a combined magnetic resonance-positron emission tomography device 1 according to an embodiment of the invention. The device includes a magnetic resonance imaging device 2 and a PET imaging device 3. Instead of the PET imaging device 3, it is also conceivable to use a different radionuclide imaging device such as a SPECT imaging device. In addition to further components known to the person skilled in the art, the PET imaging device 3 comprises a radiation detector unit 6 for positron recombination radiation with an energy of approximately 511 keV.

An example embodiment comprises in this case scintillation crystals which convert the high-energy PET radiation into photons which are detectable by photo diodes. During the annihilation of a positron and an electron (pairing), two photons are produced with an energy of respectively ca. 511 keV, the trajectories thereof enclosing an angle of 180°. By way of the PET radiation detector 6, the coincidence of this photon pair may be measured so that a back-calculation of the trajectories and, as a result, a spatial determination of the origin of the detected photon pairs is possible in an object to be examined U. This back-calculation permits the determination of the spatial concentration of the tracer in the object to be examined U. In combination with the image information of the magnetic resonance imaging device 2, high resolution, detailed combination images of the object to be examined U may thus be acquired, in which the tracer concentration is able to be identified in its anatomical environment.

In the example embodiment, the radiation detector unit 6 is arranged in an annular manner around the center axis ZL of a measuring space 4 of the combined magnetic resonance-positron emission tomography device 1, which is oriented substantially parallel to a spatial direction z, which coincides with the alignment of a base magnetic field of the combined magnetic resonance-positron emission tomography device 1. The annular arrangement permits a substantially identical removal of an object to be examined U arranged in the center or in the region of the center axis ZL of the measuring space 2, at all image points of the radiation detector unit 6. For positioning the object to be examined U, a patient table 5 is arranged in the measuring space 2, by which the object to be examined U is able to be displaced along the center axis ZL.

For magnetic resonance imaging, the measuring space 2 of the combined magnetic resonance-positron emission tomography device 1 is surrounded by a superconducting base field magnet, which produces a uniform base magnetic field in the measuring space 2, which is oriented in the z-direction. The current measuring range of the object to be examined U should then be located within a homogenous volume of the base magnetic field. Moreover, the combined magnetic resonance-positron emission tomography device 1 has a transmission coil, generally a body coil, installed fixedly in the device, around the measuring space, by means of which high-frequency signals may be transmitted at the desired magnetic resonance frequency, in order to activate the spin in a specific region of the object to be examined.

Moreover, the combined magnetic resonance-positron emission tomography device 1 comprises a gradient coil system by which the positional resolution may be achieved of magnetic resonance image information. The magnetic resonance image information i.e. the magnetic resonance signals excited in the object to be examined, are in this case generally detected by way of local coils. Moreover, the local coils may also be configured for producing high frequency fields, which serve to activate the spin and/or the magnetic resonance signals produced may be detected by means of the body coil.

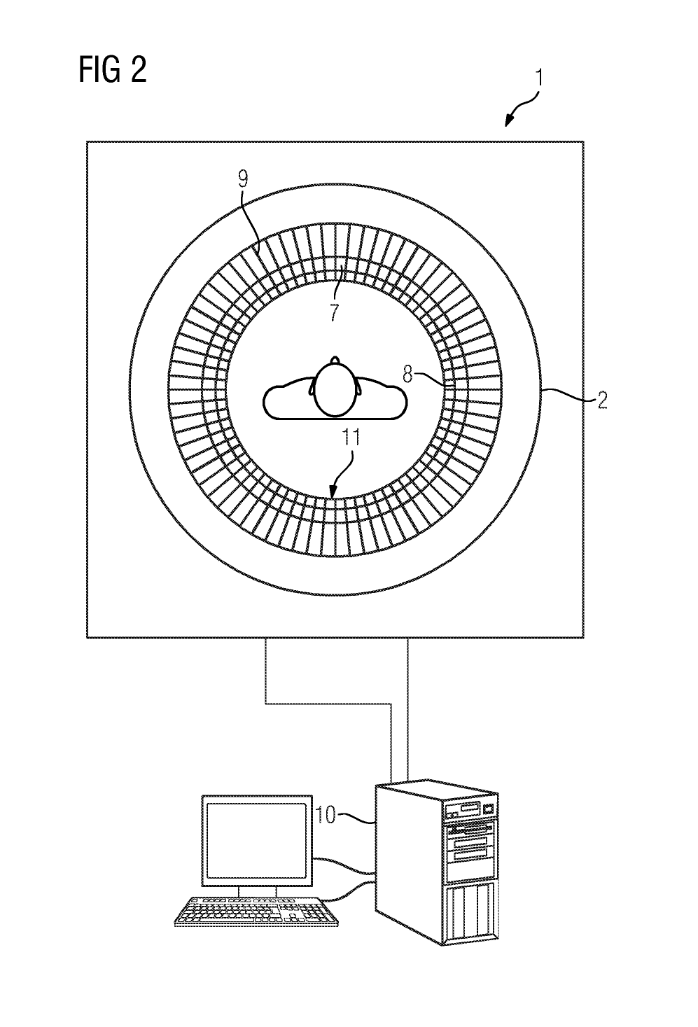

FIG. 2 shows a cross section of a combined magnetic resonance-positron emission tomography device 1 according to an embodiment of the invention. The device 1 includes a magnetic resonance imaging device 2. The longitudinal direction z extends in this case at right angles to the drawing plane.

Within the magnetic resonance imaging device 2, a plurality of radiation detector elements 11 (also PET detection elements) are arranged coaxially opposing one another in pairs around the longitudinal direction z. The PET detection elements 11 preferably includes an array of avalanche photo diodes (or APD photo diode array) 7 with an array of LSO crystals 8 arranged upstream and an electrical amplifier circuit (AMP) 6. Embodiments of the invention are, however, not limited to the PET detection elements 11 with the APD photo diode array 7 and the array of LSO crystals 9 arranged upstream, but equally other types of photo diodes, crystals and devices may also be used for the detection. All the radiation detector elements 11 combined together produce the radiation detector unit 6.

The image processing for the superimposed MR image display and PET image display is carried out by way of a computer 10.

In this example embodiment, the detection unit according to an embodiment of the invention and the generator unit according to an embodiment of the invention are a component of the computer 10.

In the longitudinal direction z thereof, the magnetic resonance imaging device 2 defines a cylindrical first field of view. The plurality of PET detection elements 11 defines in the longitudinal direction z a cylindrical second field of view. According to an embodiment of the invention, the second field of view of the PET detection elements 11 substantially coincides with the first field of view of the magnetic resonance imaging device 2. This is implemented by a corresponding adaptation of the density of the arrangement of PET detection elements 11 in the longitudinal direction z.

Different components of an imaging device may alter, absorb or scatter the photons produced during the electron-positron recombinations of the tracer, so that a back-calculation of the condition of the object to be examined U is falsified and/or an evaluation of the image information is associated with high losses.

A measurement of these losses is the so-called attenuation correction factor (ATF), the determination thereof being undertaken by means of a so-called attenuation map (or μ-map). To this end, initially by way of a phantom radiation source U, a counting rate of radionuclide emission radiation is determined (the counting rate corresponds to a radiation density of the radionuclide emission radiation per image point), wherein the components are arranged in an operating position. The attenuation correction factor may then be determined by means of a comparison measurement in which the components are removed from the measuring space 4. The attenuation correction factor, in particular specifically for each straight line between two radiation detector elements 11 (also called line of response), provides a scale value with which the counting rate has to be multiplied in order to obtain the value of the comparison measurement. In other words, this means that the greater the determined attenuation correction factor, the lower the transmission of the radionuclide emission radiation and the greater the impairment of the radionuclide-based imaging.

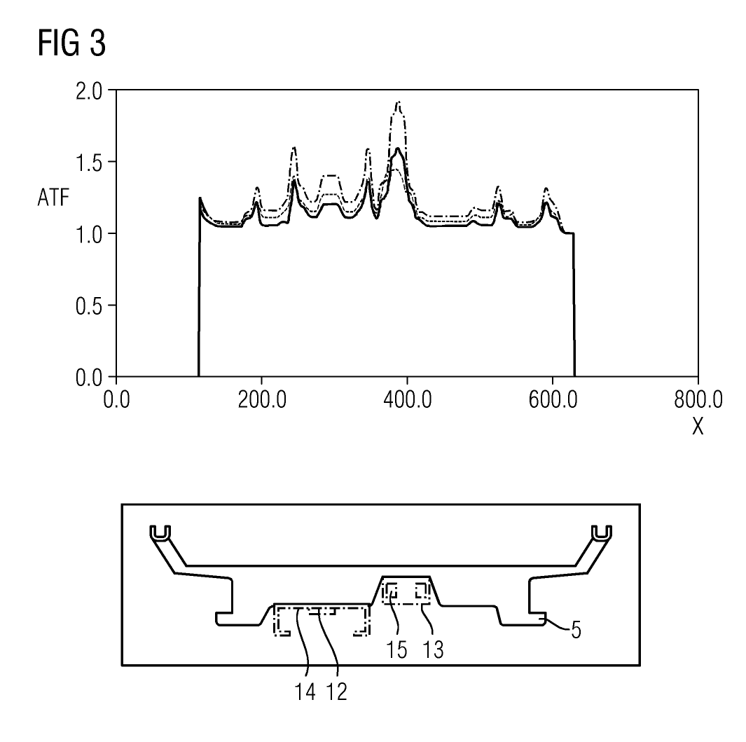

FIG. 3 shows a diagram for determining the attenuation correction factor for a plurality of functional components shown below in a patient table 5. In this case, a patient table 5 is shown in outline in the lower portion of the image, in the diagram shown thereabove, the associated “μ-map” is shown, i.e. the spatial assignment of the attenuation correction factor (a dimensionless scaling factor) to image points of the PET detector 6 along a line extending transversely through the patient table 5 (in the x-direction with units in mm) for “lines of response” located perpendicular thereto.

As may be identified from the spatial assignment, the components 12, 13 of the patient table 5 marked in dashed lines require the greatest attenuation correction factors. A toothed rod manufactured from metal, with an associated bearing rail 14 for moving the patient table 5 results, for example, in a peak value of the attenuation correction factor of approximately 1.5 during operation of the associated combined magnetic resonance-positron emission tomography device 1. The centrally arranged electronic channel 15 with a plurality of metal conductors, printed circuit boards, blocking devices for surface waves and other shielding devices for high-frequency radiation generates an even greater peak value of the attenuation correction factor of approximately 1.9. In other words, almost 50% of the radionuclide emission radiation which relates to this component is absorbed or scattered.

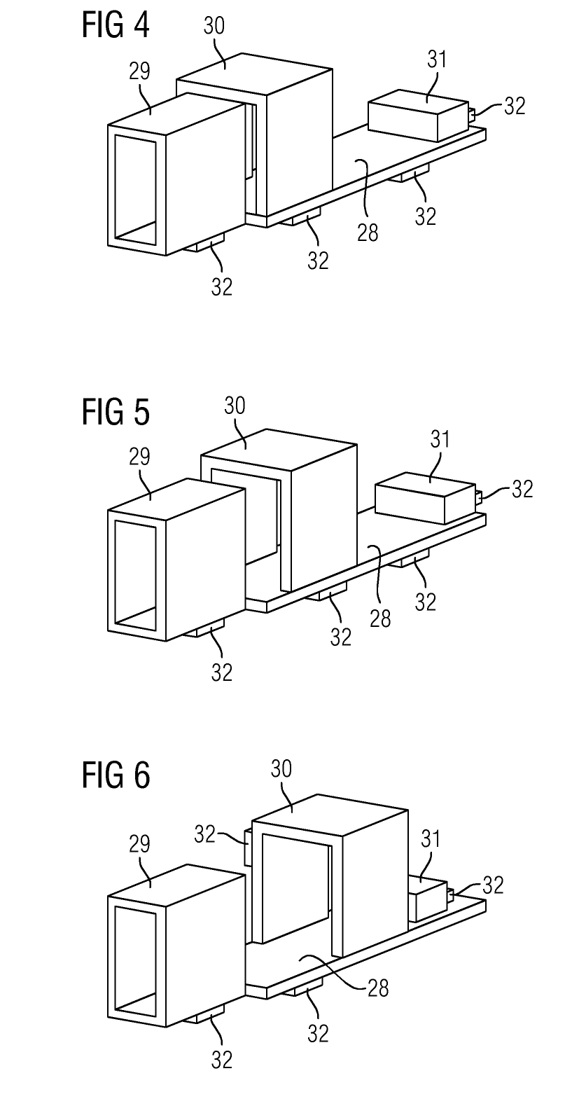

FIG. 4 shows an option for arranging different hardware components 28, 29, 30, 31 which in each case are provided with an RFID transponder 32. After establishing the desired positions for the hardware components 28, 29, 30, 31 and after monitoring the specific positions by reading the identifying code of the RFID transponder 32, a global attenuation map 27 may be determined in a simple manner by way of the solution according to the invention.

FIG. 5 shows a second option for arranging different hardware components 28, 29, 30, 31.

FIG. 6 shows a third option for arranging different hardware components 28, 29, 30, 31.

In all cases shown in FIGS. 4-6, it is not necessary to complete a separate recording of the complete set-up of the examination area. The method according to an embodiment of the invention determines the associated global attenuation map 27 from the established positions of the hardware components 28, 29, 30, 31.

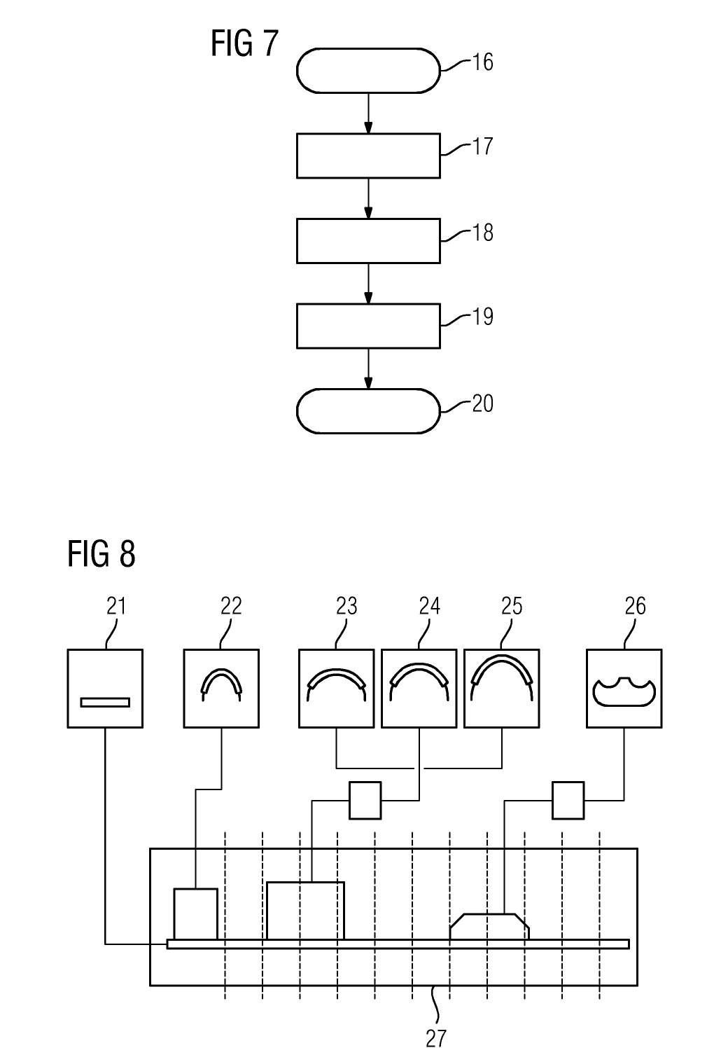

FIG. 7 shows a flow diagram of a method according to an embodiment of the invention. The method comprises the method steps 16 to 20, wherein parts of the description including the corresponding reference numerals used in connection with other figures are used in the description of the method steps 16 to 20.

In the method step 16, the procedure is started for generating a global attenuation map used for attenuation correction of positron emission tomography image data sets, in a combined magnetic resonance-positron emission tomography device 1 and during the method step 17, the hardware components of the combined magnetic resonance-positron emission tomography device 1, which are used when generating the desired image data set, are detected.

In the method step 18, the positions of the detected hardware components relative to a patient support of the combined magnetic resonance-positron emission tomography device are determined and in the method step 19 the global attenuation map is finally generated as a function of the hardware components and the end 20 of the process is reached.

FIG. 8 shows a schematic view of the generation of a global attenuation map 27 using local attenuation maps 21, 22, 23, 24, 25, 26 of different hardware components. Such hardware components may, for example, comprise EKG measuring devices, arm supports and leg supports, body coils and other components used when recording positron emission tomography image data sets. The attenuation maps 21, 22, 23, 24, 25, 26, 27 shown in the figure, solely serve for illustration purposes, as the outlines of the hardware components themselves are generally not visible on an attenuation map.

The modular embodiment shown of the method permits a user to assign different positions of a specific set-up of an examination area to different hardware components. In this case, the local attenuation maps 21, 22, 23, 24, 25, 26 underlying the hardware components are automatically combined to form a global attenuation map 27 which may then be used for an examination using a combined magnetic resonance-positron emission tomography device 1. In this case, not all local attenuation maps 21, 22, 23, 24, 25, 26 necessarily have to be used.

As the user has to establish the individual positions of the hardware components, the layout of the examination area is monitored and as the local attenuation maps 21, 22, 23, 24, 25, 26 of the individual hardware components are already present, additional recordings of the hardware components are not necessary.

In this case, the local attenuation maps 21, 22, 23, 24, 25, 26 of a data bank linked to the combined magnetic resonance-positron emission tomography device 1 may be provided but it is also possible that the local attenuation maps 21, 22, 23, 24, 25, 26 are provided in a storage unit of the combined magnetic resonance-positron emission tomography device 1.

Moreover, the hardware components used may be provided with an RFID transponder 32 in order to be able to monitor the positions of the hardware components by reading an identifying code of the RFID transponder 32.

It is also possible to monitor the specific positions of the hardware components by a video monitoring system or by light pulse measurements.

In summary, an embodiment of the invention relates to a method, a computer program product and a computer readable storage medium for generating a global attenuation map used for attenuation correction of positron emission tomography image data sets, in a combined magnetic resonance-positron emission tomography device. Within the scope of the detection of hardware components of the combined magnetic resonance-positron emission tomography device and the determination of the positions of the detected hardware components relative to a patient support, the global attenuation map is generated as a function of the detected hardware components.

What is claimed is:

1. A method for generating a global attenuation map used for attenuation correction of positron emission tomography image data sets in a combined magnetic resonance-positron emission tomography device, the method comprising:
detecting hardware components of the combined magnetic resonance-positron emission tomography device, useable when generating desired image data sets, via a detection unit;
determining positions of the detected hardware components, relative to a patient support of the combined magnetic resonance-positron emission tomography device, via the detection unit; and
generating the global attenuation map, as a function of the detected hardware components, via a generator unit.

2. The method of claim 1, wherein at least one of the detection unit and the generator unit are integrated in the combined magnetic resonance-positron emission tomography device.

3. The method of claim 1, wherein local attenuation maps of the detected hardware components are used for generating the global attenuation map via the generator unit.

4. The method of claim 3, wherein the local attenuation maps for the detected hardware components are determined by the method of claim 3.

5. The method of claim 3, wherein the local attenuation maps for the detected hardware components are provided by a data bank linked to the detection unit.

6. The method of claim 1, wherein the detected hardware components and the positions of the hardware components are monitored by a user before generating the global attenuation map.

7. The method of claim 1, wherein the detected hardware components are provided with an RFID transponder.

8. The method of claim 7, wherein the specific positions of the hardware components are monitored by reading an identifying code of the RFID transponder.

9. The method of claim 1, wherein the specific positions of the hardware components are monitored by a video monitoring system.

10. The method of claim 1, wherein the specific positions of the hardware components are monitored by light pulse measurements.

11. A combined magnetic resonance-positron emission tomography device for generating a global attenuation map used for attenuation correction of positron emission tomography image data sets, the combined magnetic resonance-positron emission tomography device comprising:
a detection unit, configured to detect hardware components of the combined magnetic resonance-positron emission tomography device, useable when generating desired image data sets;
a processing device configured to determine positions of the detected hardware components relative to a patient support of the combined magnetic resonance-positron emission tomography device; and
a generator unit configured to generate the global attenuation map as a function of the detected hardware components.

12. A computer program product, comprising a program, loadable directly into a memory of a programmable control device of a combined magnetic resonance-positron emission tomography device in order to implement the method of claim 1 when the program is executed in the programmable control device of the combined magnetic resonance-positron emission tomography device.

13. Electronically readable data carriers with electronically readable control information stored therein, designed such that when the data carrier is used in a control device of a combined magnetic resonance-positron emission tomography device, said data carriers carry out the method of claim 1.

14. The method of claim 2, wherein local attenuation maps of the detected hardware components are used for generating the global attenuation map via the generator unit.

15. The method of claim 2, wherein the detected hardware components and the positions of the hardware components are monitored by a user before generating the global attenuation map.

16. The method of claim 2, wherein the detected hardware components are provided with an RFID transponder.

17. The method of claim 2, wherein the specific positions of the hardware components are monitored by a video monitoring system.

18. The method of claim 2, wherein the specific positions of the hardware components are monitored by light pulse measurements.
